(19) United States
(12) Patent Application Publication
(10) Pub. No.: US 2014/0227513 A1
(43) Pub. Date: Aug. 14, 2014

(54) BIOPLASTIC MOLDED BODY AND METHOD FOR PRODUCING BIOPLASTIC MOLDED BODY

(71) Applicant: NEC CORPORATION, Tokyo (JP)

(72) Inventor: Yukihiro Kiuchi, Tokyo (JP)

(73) Assignee: NEC CORPORATION, Tokyo (JP)

(21) Appl. No.: 14/346,951

(22) PCT Filed: Sep. 19, 2012
(86) PCT No.: PCT/JP2012/073905

§ 371 Date: Mar. 24, 2014

(30) Foreign Application Priority Data
Sep. 27, 2011 (JP) 2011-211463

(51) Int. Cl. H05K 9/00

(52) U.S. Cl. CPC H05K 9/0045
USPC 428/336; 428/425.8; 427/404

(57) ABSTRACT

The present invention relates to an electronic equipment case including: a polylactic acid resin-based substrate; a polylactic acid resin-based adhesion layer that is coated on the substrate; a resin layer that has high adhesiveness with the adhesion layer and is capable of being plated with a metal; and a metal plating that is formed on the resin layer. According to the present invention, a bioplastic molded body having sufficient electromagnetic wave shielding performance and a high-adhesion metal plating can be provided.

### TECHNICAL FIELD

The present invention relates to a bioplastic molded body which is used as an electronic equipment case or the like requiring electromagnetic wave shielding performance; and a method of producing a bioplastic molded body.

Priority is claimed on Japanese Patent Application No. 2011-211463, filed Sep. 27, 2011, the content of which is incorporated herein by reference.

### BACKGROUND ART

In recent years, from the viewpoint of environmental protection, studies have been made to reduce the amount of petroleum-derived materials used and to instead use plant-derived materials.

Examples of the petroleum-based materials include synthetic resins such as polycarbonate resins. PC (polycarbonate)/ABS (acrylonitrile butadiene styrene) copolymers, or aromatic nylons. These petroleum-derived materials have advantageous properties such as light weight, high strength, or long life and are used in various fields. However, when disposed by incineration, these petroleum-derived materials have a problem in that the burden on the environment is high, for example, an incinerator is damaged by high heat generated from the materials, or a large amount of carbon dioxide is emitted. Further, when disposed in a landfill, the petroleum-derived materials have high volume occupancy and are not decomposed in the soil, which results in a shortage of land disposal facilities or sites. In addition, when dissipated into the nature, the petroleum-derived materials destroy the environment, for example, have adverse effects on wild animals. In addition, since petroleum as a base material is a resource with limited reserves, plant-derived plastic materials (bioplastics) have been studied as alternative materials.

Among the bioplastics, polylactic acid resin, in particular, is formed of starches of plants such as corn or sweet potato, is reduced in molecular weight by hydrolysis in the soil, and finally is decomposed into carbon dioxide and water by microorganisms. In addition, when disposed by incineration, polylactic acid resin has characteristics in that the heat quantity generated is small, and the carbon dioxide emission is also small. Further, since plants as a base material absorb carbon dioxide during their growth, polylactic acid resin has attracted attention as a material which places a low burden on the environment.

In addition, polylactic acid resin has properties such as high rigidity, relatively high tensile strength, and high transparency, and molded products thereof have begun to be applied to various fields such as food containers, horticultural sheets, electronic equipment cases, or automobile components (for example refer to PTL 1). Among molded products of synthetic resins, there are many examples in which a synthetic resin coating material such as acrylic resin or urethane resin is applied on a surface of a molded product to improve surface conditions such as appearance or protection against scratches. Likewise, regarding molded products of polylactic acid resin, coating materials used to add functions have been actively developed. For example, a polylactic acid resin-containing adhesive (for example refer to PTL 2) having high adhesiveness with a substrate, a coating agent (for example, refer to PTL 3), and a decorative sheet (for example, refer to PTL 4) are disclosed.

In addition, metal plating does not come into direct contact with a polylactic acid resin-based resin composition. Therefore, when a polylactic acid resin-based resin composition is used as an electronic equipment case requiring electromagnetic wave shielding performance, it is necessary that a metal plate, an aluminum foil, or the like be attached on a molded product. Therefore, there is a problem in that the weight of a product is increased. In addition, it is extremely difficult to apply the polylactic acid resin-based resin composition to a molded product having almost no space on the molded product to which it is difficult to attach a metal plate or an aluminum foil, and which requires electromagnetic wave shielding performance. Thus there is a problem in that the degree of freedom in product design is greatly decreased.

To solve these problems, as a method of plating a resin composition to shield electromagnetic waves, a method is proposed in which a coating material, which is formed of an ABS resin, is applied on a plating-required portion of a polycarbonate resin or an alloy resin of polycarbonate resin/ABS resin which is a low-adhesion and non-conductive material, followed by etching and electroless plating (for example, refer to PTL 5).

### DOCUMENTS OF RELATED ART

### Patent Documents

[PTL 1] Japanese Unexamined Patent Application, First Publication No. 2008-150560, paragraph [0029]

[PTL 2] Japanese Unexamined Patent Application, First Publication No. 2004-231797

[PTL 3] Japanese Unexamined Patent Application. First Publication No. 2006-291000

[PTL 4] Japanese Unexamined Patent Application. First Publication No. 2011-152795

[PTL 5] Japanese Patent No. 3069809

### SUMMARY OF THE INVENTION

### Problems to be Solved by the Invention

However, the coating material which is formed of an ABS resin does not come into direct contact with the polylactic acid resin-based resin composition (bioplastic), and the polylactic acid resin-based resin composition is decomposed by an etchant. Accordingly, there is a problem in that the method of PTL 5 cannot be applied to a case where the polylactic acid resin-based resin composition is plated with a metal.

In order to solve the above-described problems, according to the present invention, a polylactic acid resin-based adhesion layer is formed on a polylactic acid resin-based resin composition, a resin layer that has high adhesiveness with the adhesion layer and is capable of being plated with a metal is formed on the adhesion layer, and the resin layer is plated with a metal using a vacuum deposition method. As a result, a molded body of a polylactic acid resin-based resin composition (bioplastic) having a high-adhesion metal plating can be obtained.

The present invention has been made in consideration of the above-described circumstances, and an object thereof is to provide a bioplastic molded body having sufficient electromagnetic wave shielding performance and a high-adhesion metal plating.

### Means to Solve the Problems

In order to achieve the above-described object, the present invention adopts the following means. That is, a bioplastic molded body according to the present invention includes: a polylactic acid resin-based resin composition; a polylactic acid resin-based adhesion layer that is coated on the resin composition; a resin layer that has high adhesiveness with the adhesion layer and is capable of being plated with a metal; and a metal plating that is formed on the resin layer.

In addition, a method of producing a bioplastic molded body according to the present invention includes: a step of coating a polylactic acid resin-based adhesion layer on a polylactic acid resin-based resin composition; a step of coating a resin layer, which has high adhesiveness with the adhesion layer and is capable of being plated with a metal, on the adhesion layer; and a step of plating the resin layer with a metal.

That is, the present invention relates to the following.

(1) A bioplastic molded body including: a polylactic acid resin-based substrate; a polylactic acid resin-based adhesion layer that is coated on the substrate; a resin layer that has high adhesiveness with the adhesion layer and is capable of being plated with a metal; and a metal plating that is formed on the resin layer.

(2) The bioplastic molded body according to (1), wherein the adhesion layer contains a polylactic acid resin, a natural product-based tackifying resin, an anti-hydrolysis agent, and a polyfunctional isocyanate.

(3) The bioplastic molded body according to (1) or (2), wherein the mass ratio of plant-derived components to the substrate is 25 mass % to 100 mass %.

(4) The bioplastic molded body according to any one of (1) to (3), wherein the resin layer contains a compound having a functional group capable of hydrogen bonding or a compound having an unsaturated double bond.

(5) The bioplastic molded body according to any one of (1) to (4), wherein the thickness of the adhesion layer is 5 μm to 20 μm.

(6) A method of producing a bioplastic molded body, the method including: coating a polylactic acid resin-based adhesion layer coating material on a polylactic acid resin-based substrate to form an adhesion layer on the substrate; coating a resin layer coating material, which has high adhesiveness with the adhesion layer and is capable of being plated with a metal, on the adhesion layer to form a resin layer on the adhesion layer, and plating the resin layer with a metal.

### Effect of the Invention

According to the bioplastic molded body according to the present invention, the electromagnetic wave shielding performance is sufficient, and the adhesion of metal plating is high.

### BRIEF DESCRIPTION OF THE DRAWINGS

FIG. 1 is a cross-sectional view schematically illustrating a bioplastic molded body according to an embodiment of the present invention.

FIG. 2 is an image illustrating a delamination state of plating according to Example 1.

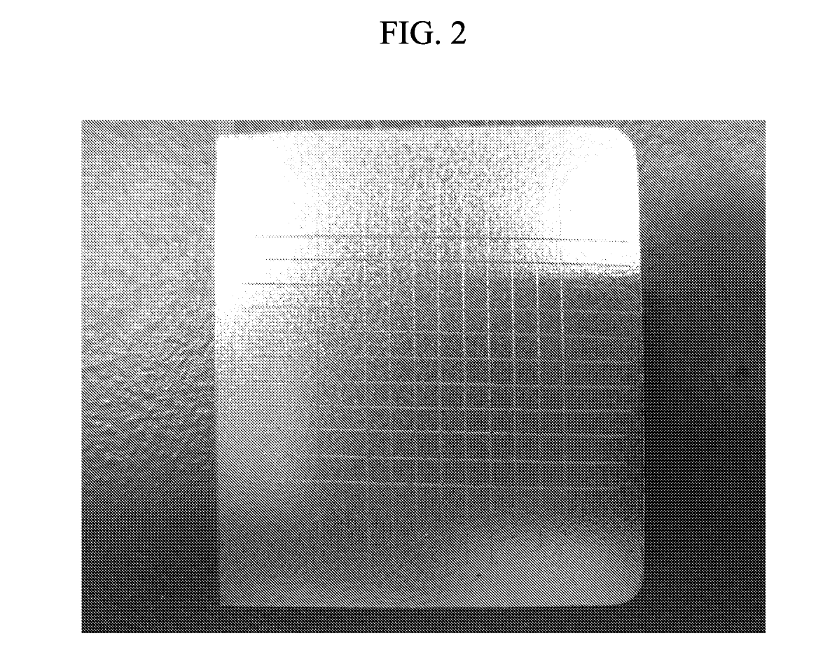

FIG. 3 is an image illustrating a delamination state of plating according to Comparative Example 2.

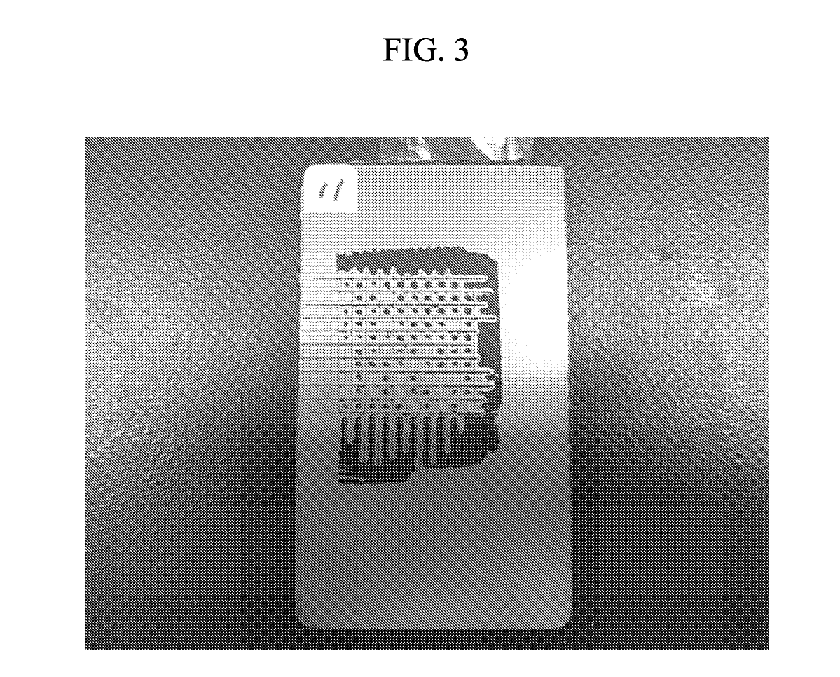

FIG. 4 is an image illustrating a delamination state of plating according to Comparative Example 3.

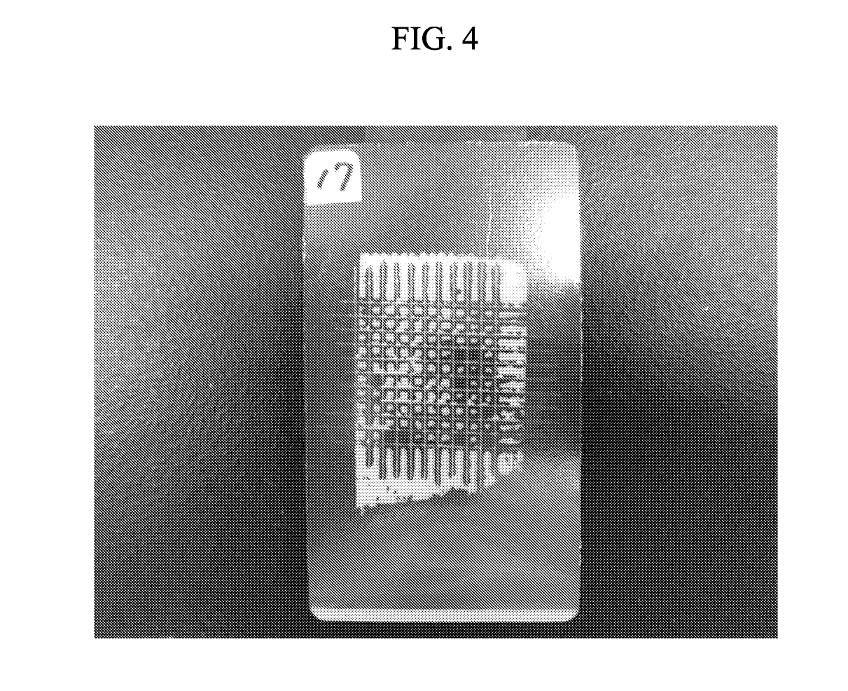

FIG. 5 is an image illustrating a delamination state of plating according to Comparative Example 4.

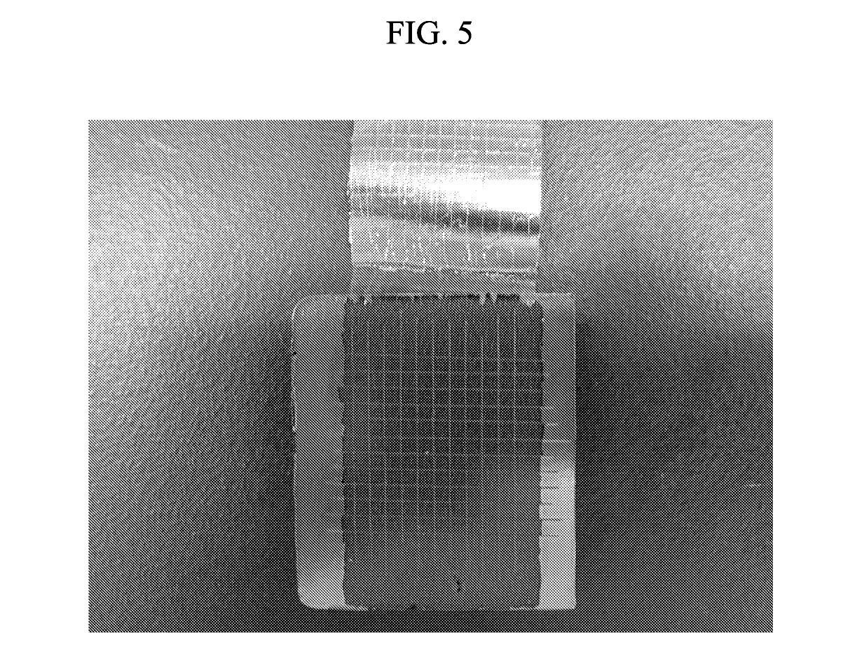

### DETAILED DESCRIPTION OF THE INVENTION

The present invention will be described in detail using an embodiment but is not limited to the descriptions of the embodiment. In addition, the embodiment may be modified as long as the effects of the present invention can be obtained.

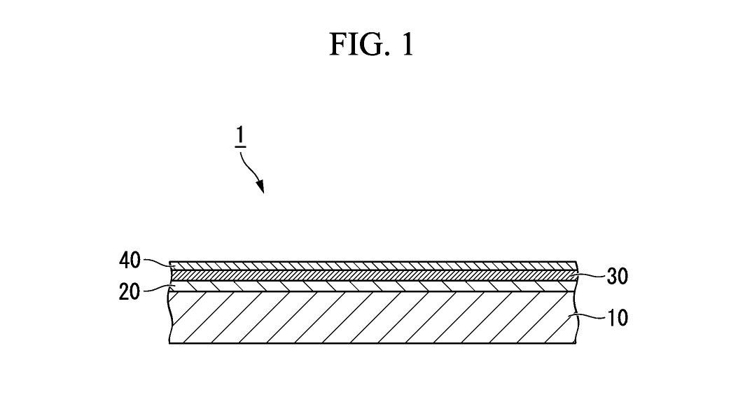

An electronic equipment case 1 (bioplastic molded body) according to an embodiment of the present invention includes, as illustrated in FIG. 1, a polylactic acid resin-based substrate 10 (resin composition); an adhesion layer 20 that is coated on the substrate 10; a resin layer 30 that is adhered on the adhesion layer 20; and a metal plating 40 that is formed on the resin layer 30.

### (Substrate)

The substrate 10 contains a polylactic acid resin-based resin composition.

In addition to the polylactic acid resin as a major component, the resin composition may further contain a filler, a pigment, a thermal stabilizer, an antioxidant, an anti-weathering agent, a plasticizer, a lubricant, a release agent, an antistatic agent, a filling material, a crystal nucleating agent, a flame retardant, an anti-hydrolysis agent, or the like.

It is preferable that the polylactic acid resin-based resin composition contained in the substrate 10 contain the polylactic acid resin in an amount of 20 mass % to 100 mass % with respect to the total amount of the resin composition.

The polylactic acid resin contained in the substrate 10 is a resin formed of polylactic acid. According to the present invention, components of the polylactic acid resin are not limited, and poly-L-lactic acid, poly-D-lactic acid, or a mixture or copolymer thereof is preferably used. In particular, from the viewpoint of heat resistance, in the polylactic acid resin, a mass ratio of a crystalline polylactic acid having an optical purity of 90% or higher to a polylactic acid having an optical purity of lower than 90% is 100/0 to 10/90, preferably 100/0 to 25/75, more preferably 100/0 to 50/50, and still more preferably 100/0 to 90/10.

In addition to the polylactic acid resin, the polylactic acid resin-based resin composition contained in the substrate 10 may further contain a petroleum-based resin such as a polycarbonate resin, an ABS resin, or a PMMA resin.

Further, the mass average molecular weight (Mw) of the polylactic acid resin contained in the substrate 10 is preferably 2000 to 200000 in terms of polystyrene.

In addition, examples of the filler contained in the substrate 10 include metal oxides such as magnesium oxide, barium oxide, titanium oxide, aluminum oxide, or zinc oxide; silicas; and layered silicate minerals. The average particle size of the filler is preferably 0.1 μm to 80 μm. The average particle size is a value measured by a laser diffraction scattering method. In addition, the filler may be surface-treated with a silane coupling agent or may be granulated to be granular with a binder such as an epoxy-based, urethane-based, or acrylic binder.

In addition, examples of the thermal stabilizer contained in the substrate 10 include hindered phenols, phosphorus compounds, hindered amines, sulfur compounds, copper compounds, halides of alkali metals, and mixtures thereof.

As the flame retardant contained in the substrate 10, a well-known flame retardant can be used, for example, metal hydrates such as aluminum hydroxide or magnesium hydroxide; various phosphorus-based flame retardants such as phosphoric acid esters or phosphazene compounds; carbonization promoters such as phenolic resins; or anti-dripping agents such as polytetrafluoroethylene.

In addition, examples of the filling material contained in the substrate 10 include inorganic filling materials such as talc, calcium carbonate, silica, alumina, magnesium oxide, or glass fiber, and organic filling materials including natural products such as starch, cellulose fine particles, wood flour, bean curd refuse, chaff, or kenaf, modified products thereof, and synthetic organic fibers synthesized using polyamide, polyarylate, or the like.

In addition, examples of the crystal nucleating agent contained in the substrate 10 include inorganic crystal nucleating agents such as talc or kaolin; and organic crystal nucleating agents such as a sorbitol compound, benzoic acid and compounds thereof, metal salts of organic materials containing phosphorus and nitrogen with divalent metal ions of zinc or the like, amide compounds or rosin compounds.

The components constituting the substrate 10 and the mixing ratios thereof are not limited to this embodiment. However, the mass ratio of plant-derived components to the substrate 10 is preferably 25 mass % to 100 mass %. Further, the mass ratio of plant-derived components is more preferably 40 mass % to 90 mass % because the burden on the environment is low and the performance of the electronic equipment case 1 can be satisfied. When the mass ratio of plant-derived components is lower than 25 mass %, it is difficult to achieve one of the objects of the present invention which reduces the environmental impact.

In addition, a method of producing the substrate 10 is not particularly limited. For example, the substrate 10 can be produced by performing melt-kneading using a melt-kneading machine such as a single screw extruder or a twin screw extruder and then performing molding. A method of kneading the substrate 10 is not limited. For example, all the raw materials may be melt-kneaded in a batch process, or a part of the raw materials may be kneaded in advance and the other raw materials may be melt-kneaded.

In addition, as described above, as long as the effects of the present invention are not impaired, a pigment, a plasticizer, a lubricant, an antioxidant, a thermal stabilizer, a release agent, a flame retardant, an anti-hydrolysis agent, a filler, an anti-weathering agent, an antistatic agent, a filling material, a crystal nucleating agent, or the like is added to the substrate 10.

A molding method of the obtained melt-kneaded product is not particularly limited, and examples thereof include injection molding, extrusion molding, inflation molding, transfer molding, or press molding. The substrate 10 can be obtained by molding a melt-kneaded product using the above-described molding methods.

### (Adhesion Layer)

The adhesion layer 20 constituting the electronic equipment case 1 contains a polylactic acid resin as a major component. It is preferable that the adhesion layer 20 contain, as coating film components, a polylactic acid resin, a natural product-based tackifying resin, an anti-hydrolysis agent, and a polyfunctional isocyanate.

In addition to the resin components, the adhesion layer 20 may further contain at least one material selected from the group consisting of a pigment, an inorganic filler, and a bright material.

In the polylactic acid resin-based adhesion layer 20, the content of the polylactic acid resin is 20 mass % to 100 mass % and more preferably 20 mass % to 80 mass % with respect to the total amount of the adhesion layer.

The polylactic acid resin which is contained as a part of the coating film components of the adhesion layer 20 is a resin formed of polylactic acid. In the present invention, the polylactic acid resin component is not limited, and poly-L-lactic acid, poly-D-lactic acid, or a mixture or copolymer thereof is preferably used. In addition, the hydroxyl value of the polylactic acid resin is preferably 1 mg KOH/g to 50 mg KOH/g. When the hydroxyl value is less than 1 mg KOH/g, the crosslink density of a urethane bond, through which a hydroxyl group of the polylactic acid resin binds to an isocyanate group of the polyfunctional isocyanate, is not sufficiently obtained. As a result, the water resistance and the chemical resistance of the adhesion layer 20 may be decreased. In addition, when the hydroxyl value is greater than 50 mg KOH/g, the crosslink density of the urethane bond is excessive. As a result, a coating film is excessively cured and shrunk, and the adhesion of the adhesion layer 20 with the substrate 10 may be decreased.

In addition, the mass average molecular weight Mw of the polylactic acid resin, which is contained as a part of the coating film components of the adhesion layer 20, is preferably 2000 to 70000 in terms of polystyrene. When the mass average molecular weight Mw is less than 2000, the strength of a coating film may be insufficient. On the other hand, when the mass average molecular weight Mw is greater than 70000, the viscosity of a coating material is excessively increased, and it is difficult to form a thick coating film. As a result, the workability may be decreased, and it may be difficult to obtain a smooth coating film.

The natural product-based tackifying resin, which is contained as a part of the coating film components of the adhesion layer 20, is a compound having a polar group such as a hydroxyl group or a carboxyl group. As the natural product-based tackifying resin, for example, a terpene-based resin or a rosin-based resin is used. Examples of the terpene-based resin include a terpene resin, a terpene phenolic resin, a hydrogenated terpene resin, or an aromatic modified terpene resin. On the other hand, examples of the rosin-based resin include rosin, polymerized rosin, hydrogenated rosin, a rosin ester, a hydrogenated rosin ester, or a rosin modified phenolic resin. Among these, as the terpene-based resin, a terpene phenolic resin is more preferable.

In addition, as the natural product-based tackifying resin, one kind may be used alone, or two or more kinds may be used in combination. The mixing amount of the natural product-based tackifying resin is preferably 1 part by mass to 100 parts by mass and particularly preferably 20 parts by mass to 60 parts by mass with respect to 100 parts by mass of the polylactic acid resin. When the mixing amount of the natural product-based tackifying resin is less than 1 part by mass with respect to 100 parts by mass of the polylactic acid resin, the adhesion with the substrate 10 is insufficient. When the mixing amount is greater than 100 parts by mass, the stickiness of a coating material is increased. As a result, the handleability may deteriorate, and the strength of a coating film may be decreased.

In addition, the anti-hydrolysis agent which is contained as a part of the coating film components of the adhesion layer 20 inhibits the hydrolysis of the polylactic acid resin and imparts durability to the substrate 10 and the adhesion layer 20 which contain the polylactic acid resin. As the anti-hydrolysis agent, a material having an effect of inhibiting the hydrolysis of, typically, the polylactic acid resin or the like or the hydrolysis of an ester-based resin can be used, for example, a carbodiimide compound, an oxazoline compound, or an epoxy compound. Among the above-described compounds, a carbodiimide compound is preferable as the anti-hydrolysis agent.

In addition, the mixing amount of the anti-hydrolysis agent is preferably 0.1 mass % to 5 mass % and particularly preferably 1 mass % to 5 mass % with respect to 100 mass % of the polylactic acid resin. When the mixing amount of the anti-hydrolysis agent is less than 0.1 mass % with respect to 100 mass % of the polylactic acid resin, sufficient hydrolysis resistance may not be exhibited. When the mixing amount is greater than 5 mass %, the polylactic acid resin constituting the adhesion layer 20 is increased in molecular weight and is thickened. As a result, the wettability between the adhesion layer 20 and the substrate 10 may be significantly decreased.

In addition, the polyfunctional isocyanate which is contained as a part of the coating film components of the adhesion layer 20 functions as a crosslinking agent by an isocyanate group of the polyfunctional isocyanate binding to a hydrogen group of the polylactic acid resin through a urethane bond.

Examples of the polyfunctional isocyanate include aliphatic polyfunctional isocyanate compounds such as pentane-1,5-diisocyanate, hexamethylene diisocyanate, dicyclohexylmethane 4,4′-isocyanate, 2,2,4-trimethylhexylmethane diisocyanate, isophorone diisocyanate, or norbornene methane diisocyanate; and aromatic polyfunctional isocyanate compounds such as tolylene diisocyanate, xylylene diisocyanate, diphenylmethane diisocyanate, methylcyclohexane diisocyanate, or polymethylene polyphenyl polyisocyanate. Among these, as the polyfunctional isocyanate, aliphatic polyfunctional isocyanate compounds are preferable. In particular, pentane-1,5-diisocyanate, hexamethylene diisocyanate, or isophorone diisocyanate. The mixing amount of the polyfunctional isocyanate is preferably 20 mass % to 80 mass % and particularly preferably 30 mass % to 50 mass % with respect to 100 mass % of the polylactic acid resin. When the mixing amount is less than 20 mass %, the sufficient durability of a coating film is not obtained, and the hydrophobicity is low. As a result, the water resistance of a polylactic acid-based decorative body may be insufficient. When the mixing amount is greater than 80 mass %, the adhesion with the substrate 10 may be decreased.

In addition, as the pigment, the inorganic filler, or the bright material contained in the adhesion layer 20, a well-known material can be used. Examples of the pigment include organic pigments such as an azo compound, indanthrene, thioindigo, dioxazine, quinacridone, or phthalocyanine; and inorganic pigments such as titanium oxide, red iron oxide, or carbon black. In addition, examples of the inorganic filler include metal oxides such as magnesium oxide, barium oxide, titanium oxide, aluminum oxide, or zinc oxide; silicas; or layered silicate minerals. Examples of the bright material include aluminum flakes, pearl mica, or glass flakes. As the pigment, the inorganic filler, or the bright material, one kind may be added alone, or two or more kinds may be added in combination.

The mass ratio of plant-derived components to the coating material components of the adhesion layer 20 is preferably 25 mass % to 100 mass % with respect to the total amount of the coating film components of the adhesion layer and is more preferably 40 mass % to 75 mass % because the burden on the environment is low and the performance as the adhesion layer 20 can be satisfied. When the mass ratio of plant-derived components is lower than 25 mass %, it is difficult to achieve one of the objects of the present invention which reduces the environmental impact.

The adhesion layer 20 is formed of coating film components of an adhesion layer coating material. This adhesion layer coating material is obtained by mixing the above-described coating film components with a small amount of liquid solvent and further adding a liquid solvent to obtain a solid content concentration and a viscosity suitable for application. In addition, as long as the effects of the present invention are not impaired, for example, a plasticizer, a pigment dispersant, a curing catalyst, an ultraviolet absorber, an emulsifier, a surface conditioner, or a fluidity adjusting agent may be added to the adhesion layer 20.

After the preparation, the adhesion layer coating material is applied on the substrate 10 within a predetermined time. As an application method of the adhesion layer coating material according to the embodiment, a well-known method can be selected. For example, the adhesion layer coating material can be applied using a roll coating method, a spray coating method, a dip coating method, or a brush coating method. The adhesion layer 20 is formed by applying the adhesion layer coating material on the substrate 10 and drying and curing the adhesion layer coating material. In the present invention, application and coating have the same meaning.

However, a method of forming the adhesion layer 20 is not limited to the embodiment. For example, the adhesion layer 20 and the resin layer 30 may be formed by applying a resin layer coating material described below on a film, which is obtained by applying the adhesion layer coating material on the substrate 10 and drying the adhesion layer coating material, drying the resin layer coating material, and simultaneously curing the adhesion layer coating material and the resin layer coating material. In addition, the thickness of the adhesion layer 20 is preferably 5 μm to 20 μm. When the thickness of the adhesion layer 20 is greater than or equal to 5 μm, sufficient adhesion is obtained. When the thickness of the adhesion layer 20 is less than or equal to 20 μm, the adhesion layer 20 is economically preferable. In addition, in order to obtain the adhesion layer 20 having a desired thickness, the adhesion layer coating material may be applied once or two times or more.

In addition, as the liquid solvent which is contained in the adhesion layer coating material used for forming the adhesion layer 20, a well-known liquid solvent can be used. As the liquid solvent, an organic solvent can be used, and examples thereof include ketones such as diethyl ketone (3-pentanone), methyl propyl ketone (2-pentanone), methyl isobutyl ketone (4-methyl-2-pentanone), 2-hexanone, 5-methyl-2-hexanone, 2-heptanone, 3-heptanone, 4-heptanone, cyclopentanone, or cyclohexanone; esters such as ethyl acetate, isopropyl acetate, n-butyl acetate, isobutyl acetate, 3-methoxybutyl acetate, methyl propionate, ethyl propionate, diethyl carbonate, γ-butyrolactone, or isophorone; and hydrocarbons such as heptane, hexane, or cyclohexane.

Further, in order to further reduce the burden on the environment, a water-based medium can be used. The water-based medium is a mixture of water and a hydrophilic organic solvent. Examples of the hydrophilic organic solvent include alcohols such as methanol, ethanol, n-propanol, isopropanol, n-butanol, isobutanol, 1-ethyl-1-propanol, 2-methyl-1-butanol, n-hexanol, cyclohexanol, ethylene glycol monomethyl ether, ethylene glycol monoethyl ether, ethylene glycol monopropyl ether, or ethylene glycol monobutyl ether; ethers such as tetrahydrofuran or 1,4-dioxane; ketones such as acetone or methyl ethyl ketone; and esters such as methyl acetate, n-propyl acetate, isopropyl acetate, methyl propionate, ethyl propionate, or dimethyl carbonate. The kind of liquid solvent is not limited to the embodiment. As the liquid solvent, one liquid solvent may be used alone, or a mixture of two or more may be used. However, in consideration of the object of the present invention, it is more preferable that a toluene/xylene-free liquid solvent, which does not contain both toluene and xylene and has a lower environmental impact, be selected.

### (Resin Layer)

It is preferable that the resin layer 30 constituting the electronic equipment case 1 contain a compound having a functional group capable of hydrogen bonding or a compound having an unsaturated double bond. As the functional group capable of hydrogen bonding, for example, an acrylonitrile group, a hydroxyl group, a mercapto group, an epoxy group, an amino group, or an amide group is preferable, but the functional group capable of hydrogen bonding is not limited to these examples. In addition, as the compound having an unsaturated double bond, for example, an alkene such as ethylene, propylene, or butadiene is preferable, but the compound having an unsaturated double bond is not limited to these examples.

In order to form the resin layer 30, it is preferable that a resin layer coating material, which is formed of a thermoplastic resin such as an ABS resin, an epoxy resin, a phenolic resin, a phenoxy resin, or a polyamide resin, be used. However, the resin layer coating material is not limited to these examples.

As a solvent which is used for forming the coating material with the thermoplastic resin, at least one solvent selected from the group consisting of esters, ketones, and aromatic compounds can be used. In addition, a mixed solvent of two or more solvents may also be used. Examples of the ester solvent include ethyl acetate, butyl acetate, or isobutyl acetate. Examples of the ketone solvent include acetone, methyl ethyl ketone, methyl isobutyl ketone, or cyclohexanone. Examples of the aromatic solvent include toluene and xylene. However, in consideration of the object of the present invention, it is more preferable that a toluene/xylene-free solvent, which does not contain both toluene and xylene and has a lower environmental impact, be selected.

The resin layer coating material is obtained by mixing the thermoplastic resin with the solvent to be dissolved therein.

After the preparation, the resin layer coating material is applied on the adhesion layer 20 within a predetermined time. As an application method of the resin layer coating material according to the embodiment, for example, a well-known application method such as a roll coating method, a spray coating method, a dip coating method, or a brush coating method can be selected. The resin layer 30 is formed by applying the resin layer coating material on the adhesion layer 20 and drying the resin layer coating material.

However, a method of forming the resin layer 30 is not limited to the embodiment. As described above, the adhesion layer 20 and the resin layer 30 may be formed by applying the resin layer coating material on a film, which is obtained by applying the adhesion layer coating material on the substrate 10 and drying the adhesion layer coating material, drying the resin layer coating material, and simultaneously curing the adhesion layer coating material and the resin layer coating material. In addition, the thickness of the resin layer 30 is preferably 1 μm to 10 μm. When the thickness of the resin layer 30 is less than 1 μm, sufficient adhesion between the resin layer and the adhesion layer may not be obtained. When the thickness of the resin layer 30 is greater than 10 μm, the workability deteriorates, which is not economically preferable. In addition, in order to obtain the resin layer 30 having a desired thickness, the adhesion layer coating material may be applied once or two times or more.

The resin layer according to the present invention is a layer that has high adhesiveness with the adhesion layer and is capable of being plated with a metal. The high adhesiveness with the adhesion layer implies a state where delamination does not occur between the resin layer and the adhesion layer even when the resin layer is torn off using an adhesive tape.

### (Metal Plating)

In order to form the metal plating 40 constituting the electronic equipment case 1, a metal is not particularly limited as long as it is used for vacuum deposition plating. For example, copper, nickel, tin, a tin-based alloy, aluminum, chromium, gold, or the like can be selected. Among these metals, in order to form the metal plating 40, at least one metal selected from the group consisting of copper, nickel, tin, a tin-based alloy, and aluminum is preferably used from the viewpoints of obtaining both harmony with nature and economic efficiency.

As the vacuum deposition method, a well-known method can be selected. For example, the vacuum deposition method can be performed by heating a plating metal in a vacuum pot or the like to be evaporated and depositing the plating metal on a surface of a plating-required object such as plastic. The thickness of the metal plating layer 40 is preferably 0.1 μm to 10 μm. When the thickness of the metal plating layer 40 is less than 0.1 μm, sufficient electromagnetic wave shielding performance may not be obtained. When the thickness of the metal plating layer 40 is greater than 10 μm, the workability deteriorates, which is not economically preferable.

According to another aspect of the present invention, it is preferable that a bioplastic molded body be provided, the bioplastic molded body including:

a polylactic acid resin-based substrate;

a polylactic acid resin-based adhesion layer that is coated on the substrate;

a resin layer that has high adhesiveness with the adhesion layer and is capable of being plated with a metal; and

a metal plating that is formed on the resin layer,

in which the mass average molecular weight of the polylactic acid resin contained in the substrate is 2000 to 200000 in terms of polystyrene.

the adhesion layer contains, as coating film components, a polylactic acid resin, a natural product-based tackifying resin, an anti-hydrolysis agent, and a polyfunctional isocyanate,

the thickness of the adhesion layer is 5 μm to 20 μm,

the hydroxyl value of the polylactic acid resin contained in the adhesion layer is preferably 1 mg KOH/g to 50 mg KOH/g.

the mass average molecular weight Mw of the polylactic acid resin of the adhesion layer is preferably 2000 to 70000 in terms of polystyrene,

the natural product-based tackifying resin is at least one resin selected from the group consisting of a terpene resin, a terpene phenolic resin, a hydrogenated terpene resin, an aromatic modified terpene resin, rosin, polymerized rosin, hydrogenated rosin, a rosin ester, a hydrogenated rosin ester, and a rosin modified phenolic resin,

the anti-hydrolysis agent is at least one compound selected from the group consisting of a carbodiimide compound, an oxazoline compound, and an epoxy compound,

the polyfunctional isocyanate is at least one compound selected from the group consisting of pentane-1,5-diisocyanate, hexamethylene diisocyanate, dicyclohexylmethane 4,4′-isocyanate, 2,2,4-trimethylhexylmethane diisocyanate, isophorone diisocyanate, norbornene methane diisocyanate, tolylene diisocyanate, xylylene diisocyanate, diphenylmethane diisocyanate, methylcyclohexane diisocyanate, and polymethylene polyphenyl polyisocyanate,

the resin layer contains a compound having a functional group capable of hydrogen bonding or a compound having an unsaturated double bond,

the compound having a functional group capable of hydrogen bonding is at least one compound selected from the group consisting of polyacrylonitrile, an acrylonitrile-styrene copolymer, an epoxy resin, a phenolic resin, and a resin having a mercapto group, or an amino group, or an amide group,

the compound having an unsaturated double bond is at least one compound selected from the group consisting of ethylene, propylene, and butadiene, and

a metal contained in the metal plating is at least one metal selected from the group consisting of copper, nickel, tin, a tin-based alloy, aluminum, chromium, and gold.

According to still another aspect of the present invention, it is preferable that a bioplastic molded body be provided, the bioplastic molded body including:

a polylactic acid resin-based substrate;

a polylactic acid resin-based adhesion layer that is coated on the substrate;

a resin layer that has high adhesiveness with the adhesion layer and is capable of being plated with a metal; and

a metal plating that is formed on the resin layer.

in which the mass average molecular weight of the polylactic acid resin contained in the substrate is 2000 to 200000 in terms of polystyrene.

the adhesion layer contains a polylactic acid resin, a natural product-based tackifying resin, an anti-hydrolysis agent, and a polyfunctional isocyanate,

the thickness of the adhesion layer is 5 μm to 20 μm,

the hydroxyl value of the polylactic acid resin contained in the adhesion layer is preferably 1 mg KOH/g to 50 mg KOH/g, and

the mass average molecular weight Mw of the polylactic acid resin of the adhesion layer is preferably 2000 to 70000 in terms of polystyrene,

the natural product-based tackifying resin is a terpene phenolic resin,

the anti-hydrolysis agent is an aromatic carbodiimide compound,

the polyfunctional isocyanate is at least one compound selected from the group consisting of a trimer of hexamethylene diisocyanate and a trimer of pentane-1,5-diisocyanate,

the resin layer contains at least one resin selected from the group consisting of an ABS resin, an epoxy resin, a phenolic resin, a phenoxy resin, and a polyamide resin, and

a metal contained in the metal plating is at least one metal selected from the group consisting of copper and nickel.

### EXAMPLES

Next, the embodiment of the present invention will be described, but the present invention is not limited to these examples.

### Example 1

### (1) Preparation of Substrate 1

100 parts by mass of a polylactic acid resin (TERRAMAC TE-4000N, manufactured by Unitika Ltd., mass average molecular weight Mw in terms of polystyrene: 150000), 115.5 parts by mass of aluminum hydroxide as a flame retardant (HIGILITE HP-350, manufactured by Showa Denko K.K.), 5 parts by mass of a phosphazene compound (SPS-100, manufactured by Otsuka Chemical Co., Ltd.), 1 part by mass of an anti-dripping agent (POLYFLON MPA, manufactured by Daikin Industries, Ltd.), 2 parts by mass of an anti-hydrolysis agent (Stabaxol P, manufactured by Rhein Chemie Rheinau GmbH), 2 parts by mass of a crystal nucleating agent (ECOPROMOTE, manufactured by Nissan Chemical Industries, Ltd.), and 10 parts by mass of a plasticizer (DAIFATTY-101, manufactured by Daihachi Chemical Industry Co., Ltd.) were melted, kneaded, and extruded using a twin screw extruder (S1 KRC Kneader, manufactured by Kurimoto, Ltd.) at 180° C. The discharged resin was cut into pellets, thereby obtaining a polylactic acid resin composition. Next, using the pellets of the polylactic acid resin composition, a test piece was molded with an injection molding machine (EC20P, manufactured by Toshiba Machine Co., Ltd.). At this time, the mass ratio of plant-derived components to a substrate 1 was 42.5 mass %.

### (2) Preparation of Adhesion Layer Coating Material 1

100 parts by mass of a polylactic acid resin (BE-400, manufactured by Toyobo Co., Ltd., hydroxyl value: 3 mg KOH/g, mass average molecular weight Mw in terms of polystyrene: 43000), 30 parts by mass of terpene phenol (N-125, manufactured by Yasuhara Chemical Co., Ltd.), and 83 parts by mass (solid content: 24.9 parts by mass with respect to 100 parts by mass of the polylactic acid resin) of pigment black (ANP-L MA-100, manufactured by Toyo Ink Co., Ltd.) were dissolved in a mixed solution of 400 parts by mass of ethyl acetate and 400 parts by mass of cyclohexanone. 3 parts by mass of an aromatic carbodiimide (Elastostab H01, manufactured by Elastgran), 50 parts by mass of a trimer of hexamethylene diisocyanate (DURANATE TPA-100, manufactured by Asahi Kasei Corporation, ratio of plant components: 0 mass %) as a polyfunctional isocyanate, and 0.1 parts by mass of dibutyltin didodecanoate (manufactured by Junsei Chemical Co., Ltd.) were added to the obtained solution, thereby obtaining an adhesion layer coating material 1. At this time, the solid content concentration in the adhesion layer coating material was 19.5%.

### (3) Formation of Adhesion Layer 1

The adhesion layer coating material 1 was applied on the substrate 1 such that the thickness thereof after drying was 10 μm, followed by drying at 80° C. for 30 minutes and aging at room temperature for 72 hours. As a result, an adhesion layer 1 was formed. When actually measured, the thickness of the adhesion layer 1 was 8.0 μm.

### (4) Formation of Resin Layer 1

A resin layer coating material 1 in which 17.3 mass % of toluene, 44.9 mass % of ethyl acetate, and 37.8 mass % of an ABS resin were uniformly mixed and dispersed was prepared. The resin layer coating material 1 was applied using a spray coating method on the adhesion layer 1 formed on the substrate 1 in the above-described (3), followed by drying at 80° C. for 30 minutes. As a result, a plating sample 1 including the substrate 1, the adhesion layer 1, and the resin layer 1 was obtained.

### (5) Formation of Plating 1

The above-described plating sample 1 was set in a vacuum deposition pot. First, Cu was evaporated for 7.5 minutes, and then Ni was evaporated for 18 minutes, thereby forming a plating 1. As a result, an electronic equipment case was prepared. When actually measured, the thickness of the plating 1 was 2.4 μm including 1.5 μm of Cu and 0.9 μm of Ni.

### (6) Measurement of Resistance Value

The resistance value on the above-described plating 1 was measured in series using four probes at intervals of 5 mm. When the resistance value was lower than 0.1Ω, the electronic equipment case was determined to have sufficient electromagnetic wave shielding performance.

### (7) Measurement of Adhesion

After completion of the measurement of the resistance value in the above-described (6), 100 notches having a 1 mm×1 mm square shape were formed in a delamination test using an adhesion tape according to JIS (Japanese Industrial Standards) K5 600-5-6: 1999 “Cross-cut test”. As a result of visual inspection, cases where 20 or less delamination positions were observed (80 or more non-delamination positions were observed) were evaluated as 80 points or higher and “Pass”. Cases where no delamination positions were observed were evaluated as 100 points. Cases where more than 20 delamination positions were observed and less than 80 non-delamination positions were observed were evaluated as “Fail”, and the number of non-delamination positions was marked as a score. That is, cases where the score was lower than 80 were evaluated as “Fail”. Further, cases where the interface of a coating film was delaminated or where positions other than the squares were delaminated were also evaluated as “Fail”.

### Example 2

An electronic equipment case was prepared with the same method as that of Example 1, except that Substrate 2 was used instead of a substrate 1. The resistance value and the adhesion of this electronic equipment case were evaluated. Substrate 2 was prepared as follows. 100 parts by mass of a polylactic acid resin (TERRAMAC TE-4000N, manufactured by Unitika Ltd., mass average molecular weight in terms of polystyrene: 150000), 2 parts by mass of an anti-hydrolysis agent (Stabaxol P, manufactured by Rhein Chemie Rheinau GmbH), 2 parts by mass of a crystal nucleating agent (ECOPROMOTE, manufactured by Nissan Chemical Industries, Ltd.), 10 parts by mass of a plasticizer (DAIFATTY-101, manufactured by Daihachi Chemical Industry Co., Ltd.), and 10 parts by mass of glass fiber (CS03JAFT592, manufactured by Asahi Fiber Glass, Co., Ltd., fiber length: 3 mm) were melted, kneaded, and extruded using a twin screw extruder (S1 KRC Kneader, manufactured by Kurimoto, Ltd.) at 180° C. The discharged resin was cut into pellets, thereby obtaining a polylactic acid resin composition. Next, using the pellets of the polylactic acid resin composition, a test piece was molded with an injection molding machine (EC20P, manufactured by Toshiba Machine Co., Ltd.). At this time, the mass ratio of plant-derived components to Substrate 2 was 80.6 mass %.

### Example 3

An electronic equipment case was prepared with the same method as that of Example 1, except that the adhesion layer 2 was used instead of the adhesion layer 1. The resistance value and the adhesion of this electronic equipment case were evaluated. The adhesion layer 2 was formed using an adhesion layer coating material 2 prepared using the following method. That is, the adhesion layer coating material 2 was prepared as follows. 100 parts by mass of a polylactic acid resin (BE-400, manufactured by Toyobo Co., Ltd., hydroxyl value: 3 mg KOH/g, mass average molecular weight Mw in terms of polystyrene: 43000), 30 parts by mass of terpene phenol (N-125, manufactured by Yasuhara Chemical Co., Ltd.), and 83 parts by mass (solid content: 24.9 parts by mass with respect to 100 parts by mass of the polylactic acid resin) of pigment black (ANP-L MA-100, manufactured by Toyo Ink Co., Ltd.) were dissolved in a mixed solution of 400 parts by mass of ethyl acetate and 400 parts by mass of cyclohexanone. 3 parts by mass of an aromatic carbodiimide (Elastostab H01, manufactured by Elastgran), 50 parts by mass of a trimer of pentane-1,5-diisocyanate (ratio of plant components: 71 mass %) as a polyfunctional isocyanate, and 0.1 parts by mass of dibutyltin didodecanoate (manufactured by Junsei Chemical Co., Ltd.) were added to the obtained solution, thereby obtaining an adhesion layer coating material 2. At this time, the solid content concentration in the adhesion layer coating material 2 was 19.5%.

### Comparative Example 1

With the method of Example 1, an electronic equipment case was prepared by forming a plating 1 on a substrate 1. The resistance value and the adhesion of this electronic equipment case were evaluated.

### Comparative Example 2

With the method of Example 1, an electronic equipment case was prepared by forming the adhesion layer 1 on a substrate 1 and forming a plating 1 on the adhesion layer 1. The resistance value and the adhesion of this electronic equipment case were evaluated.

### Comparative Example 3

With the method of Example 1, an electronic equipment case was prepared by forming a resin layer 1 on a substrate 1 and forming a plating 1 on the resin layer 1. The resistance value and the adhesion of this electronic equipment case were evaluated.

### Comparative Example 4

With the method of Example 1, an electronic equipment case was prepared by forming an adhesion layer 1 on a substrate 1, applying a resin layer coating material 2, which was prepared for comparison to a resin layer coating material 1, on an adhesion layer 1 to form a resin layer 2 thereon, and forming a plating 1 on a resin layer 2. The resistance value and the adhesion of this electronic equipment case were evaluated. As a resin layer coating material 2, a two-liquid type acrylic urethane-based coating material (Econet FX Silver, manufactured by Origin ELECTRIC CO., LTD.) was used. Econet FX Silver was a TX-free (toluene/xylene-free) coating material, and a preparation method was as follows. That is, 100 parts by mass of a major component (containing an acrylic resin and a pigment as major solid components), was dissolved in a mixed solvent of 200 parts by mass of ethyl acetate, 200 parts by mass of butyl acetate, and 500 parts by mass of diisobutyl ketone. 22.2 parts by mass of a curing agent (containing a polyfunctional isocyanate compound as a major component) was added to the obtained solution. A this time, the molar ratio of OH groups contained in the acrylic resin for the functional layer coating material to NCO groups contained in the polyfunctional isocyanate compound was 1:4.

The evaluation results of the above-described Examples 1 to 3 and Comparative Examples 1 to 4 were as shown in Table 1.

TABLE 1

| | | | | Comparative | Comparative | Comparative | Comparative |
|---|---|---|---|---|---|---|---|
| | Example 1 | Example 2 | Example 3 | Example 1 | Example 2 | Example 3 | Example 4 |
| Configuration | Substrate 1 | Substrate 2 | Substrate 1 | Substrate 1 | Substrate 1 | Substrate 1 | Substrate 1 |
| | Adhesion | Adhesion | Adhesion | — | Adhesion Layer 1 | — | Adhesion Layer 1 |
| | Layer 1 | Layer 1 | Layer 2 | | | | |
| | Resin Layer 1 | Resin | Resin Layer 1 | — | — | Resin Layer 1 | Resin Layer 2 |
| | | Layer 1 | | | | | |
| | Plating 1 | Plating 1 | Plating 1 | Plating 1 | Plating 1 | Plating 1 | Plating 1 |
| Resistance | 0.04 Ω | 0.04 Ω | 0.04 Ω | 0.05 Ω | 0.05 Ω | 0.04 Ω | 0.04 Ω |
| Value | | | | | | | |
| Adhesion | Pass | Pass | Pass | Fail | Fail | Fail | Fail |
| | 100 Points | 100 Points | 100 Points | 0 Points | 24 Points | 8 Points | 0 Points |
| Observation | — | — | — | Plating was Not | Peripheral | Overall | Interface |
| Result | (Refer to FIG. | | | Adhered At All | Portions Other | Portions were | between Resin |
| (Remark) | 2) | | | | than Squares | Delaminated | Layer 2 and |
| | | | | | were | (Refer to FIG. | Plating 1 was |
| | | | | | Delaminated | 4) | Delaminated |
| | | | | | (Refer to FIG. | | (Refer to FIG. |
| | | | | | 3) | | 5) |

As clearly seen from the comparison of Examples 1 to 3 to Comparative Examples 1 to 4, a component of a polylactic acid resin-based resin composition (bioplastic molded body) having a high-adhesion metal plating can be obtained by using the method according to the present invention including: forming a polylactic aid resin-based adhesion layer on a polylactic aid resin-based substrate; forming a resin layer, which has high adhesiveness with the adhesion layer and is capable of being plated with a metal, on the adhesion layer, and plating the resin layer with a metal. In addition, this bioplastic molded body can satisfy electromagnetic wave shielding performance required in an electronic equipment case.

The various shapes and combinations of the respective components and the operation procedure described in the above-described embodiment are merely examples and can be modified in various ways based on design requirements and the like within a range not departing from the scope of the present invention.

### INDUSTRIAL APPLICABILITY

The bioplastic molded body according to the present invention can be used as a general electronic equipment case requiring electromagnetic wave shielding performance.

### DESCRIPTION OF THE REFERENCE SIGNS

1 ELECTRONIC EQUIPMENT CASE
10 SUBSTRATE
20 ADHESION LAYER
30 RESIN LAYER
40 METAL PLATING

1. A bioplastic molded body comprising:
a polylactic acid resin-based substrate;
a polylactic acid resin-based adhesion layer that is coated on the substrate;
a resin layer that has high adhesiveness with the adhesion layer and is capable of being plated with a metal; and
a metal plating that is formed on the resin layer.

2. The bioplastic molded body according to claim 1,
wherein the adhesion layer comprises a polylactic acid resin, a natural product-based tackifying resin, an anti-hydrolysis agent, and a polyfunctional isocyanate.

3. The bioplastic molded body according to claim 1,
wherein a mass ratio of plant-derived components to the substrate is 25 mass % to 100 mass %.

4. The bioplastic molded body according to claim 1,
wherein the resin layer contains one of a compound having a functional group capable of hydrogen bonding and a compound having an unsaturated double bond.

5. The bioplastic molded body according to claim 1,
wherein a thickness of the adhesion layer is 5 μm to 20 μm.

6. A method of producing a bioplastic molded body, the method comprising:
coating a polylactic acid resin-based adhesion layer coating material on a polylactic acid resin-based substrate to form an adhesion layer on the substrate;
coating a resin layer coating material, which has high adhesiveness with the adhesion layer and is capable of being plated with a metal, on the adhesion layer to form a resin layer on the adhesion layer, and
plating the resin layer with a metal.
